(19) United States
(12) Patent Application Publication
(10) Pub. No.: US 2015/0021668 A1
(43) Pub. Date: Jan. 22, 2015

(54) PHOTOSENSITIVE CELL OF AN IMAGE SENSOR

(71) Applicants: STMicroelectronics SA, Montrouge (FR); STMicroelectronics (Crolles 2) SAS, Crolles (FR)

(72) Inventors: Francois Roy, Seyssins (FR); Julien Michelot, Grenoble (FR); Pascale Mazoyer, Saint Jean Le Vieux (FR)

(21) Appl. No.: 14/335,565

(22) Filed: Jul. 18, 2014

(30) Foreign Application Priority Data
Jul. 19, 2013 (FR) 1357122

(51) Int. Cl. H01L 27/146; H01L 27/148

(52) U.S. Cl. CPC H01L 27/14616; H01L 27/14806
USPC 257/225

(57) ABSTRACT

An image sensor cell formed inside and on top of a substrate of a first conductivity type includes: a storage region of the second conductivity type; a read region of the second conductivity type; a transfer region located between the storage region and the read region; and a transfer gate topping the transfer region and which does not or does not totally top the storage region. The transfer region comprises a first area of the first conductivity type in the vicinity of the storage region, and a second area of the second conductivity type extending between the first area and the read region.

### BACKGROUND

1. Technical Field

The present application relates to an image sensor made in monolithic form, and more specifically to photosensitive cells of such an image sensor.

2. Description of the Related Art

Conventionally, an image sensor made in monolithic form comprises a plurality of photosensitive cells formed inside and on top of a semiconductor substrate. Each photosensitive cell, or pixel, of such a sensor comprises a photodiode, having its junction capacitance discharged by a photocurrent according to a received light intensity. At the end of a period, called integration period, before and after which the pixel is reset by recharging of its photodiode, photogenerated charges stored in the photodiode are transferred to a capacitive read node of the pixel via a transfer transistor. The measurement of the illumination level received by the pixel is performed by measuring the sense node voltage.

There is a need for an image sensor photosensitive cell which at least partly improves certain aspects of photosensitive cells of existing image sensors.

### BRIEF SUMMARY

One embodiment of the present disclosure provides an image sensor cell formed inside and on top of a substrate of a first conductivity type, comprising: a storage region of the second conductivity type; a read region of the second conductivity type; a transfer region located between the storage region and the read region; and a transfer gate topping the transfer region and which does not or does not totally top the storage region, wherein the transfer region comprises a first area of the first conductivity type in the vicinity of the storage region, and a second area of the second conductivity type extending between the first area and the read region.

According to an embodiment, the first and second areas both extend all the way to the surface of the substrate and have a common lateral edge.

According to an embodiment, the thickness and the doping level of the second area are selected so that: in a first operating mode where a voltage ranging between 2 and 4 V is applied to the gate, the second area is capable of storing photogenerated charges; and in a second operating mode where a voltage ranging between −1 and 0 V is applied to the gate, the second area is totally depleted of photogenerated charges.

According to an embodiment, the second area has substantially the same doping level as the read region.

According to an embodiment, the first area has substantially the same doping level as the substrate.

According to an embodiment, the storage region is a floating region of a pinned photodiode.

According to an embodiment, the storage region is entirely delimited by regions of the first conductivity type.

According to an embodiment, the storage region is topped with a region of the first conductivity type having a higher doping level than the substrate.

According to an embodiment, the first and second conductivity types respectively are type P and type N.

Another embodiment provides an image sensor comprising a plurality of cells such as described hereabove.

The foregoing and other features and advantages will be discussed in detail in the following non-limiting description of specific embodiments in connection with the accompanying drawings.

### BRIEF DESCRIPTION OF THE SEVERAL VIEWS OF THE DRAWINGS

FIG. 1 shows an electric diagram of an example of an image sensor pixel;

FIG. 2 is a partial simplified cross-section view of an example of image sensor pixel;

FIGS. 3A to 3C are voltage profiles in the pixel of FIG. 2, illustrating the behavior of this pixel during a transfer of photogenerated charges from a storage region to a read region of the pixel;

FIG. 4 is a partial simplified cross-section view of an embodiment of an image sensor pixel; and

FIGS. 5A to 5C are voltage profiles in the pixel of FIG. 4, illustrating the behavior of this pixel during a transfer of photogenerated charges from a storage region to a read region of the pixel.

### DETAILED DESCRIPTION

For clarity, the same elements have been designated with the same reference numerals in the different drawings and, further, as usual in the representation of integrated circuits, the various drawings are not to scale. Further, in the following description, unless otherwise indicated, terms “approximately”, “substantially”, “around”, and “on the order of” mean “to within 10%”, and terms referring to directions, such as overhanging, covering, topping, lateral, above, under, etc., apply to circuits arranged as illustrated in the cross-section views of the corresponding drawings.

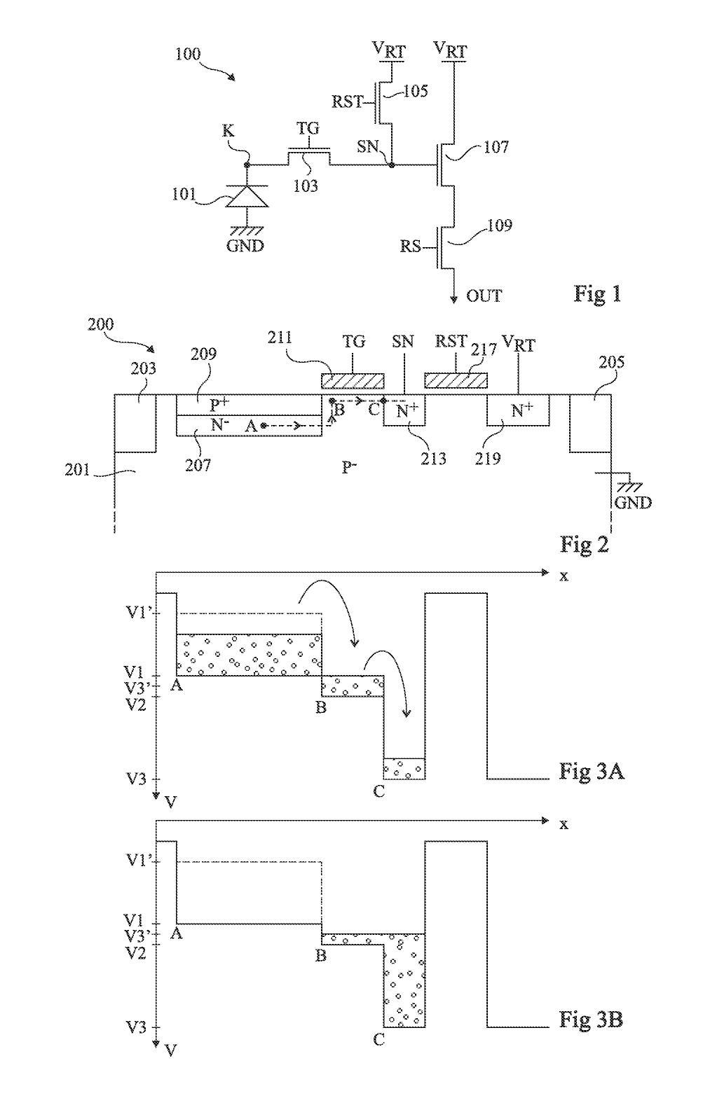

FIG. 1 illustrates an electric diagram of an example of a pixel 100 of an image sensor. Pixel 100 comprises a photodiode 101 having its anode connected to a node or rail of application of a low voltage GND, generally the ground, and having its cathode K, or storage node, coupled, via a transfer transistor 103, to a sense node SN. Sense node SN is coupled, by a reset transistor 105, to a node or rail of application of a high reset voltage V_{RT}. Sense node SN is further coupled to a track OUT coming out of the pixel, via a read stage. In this example, the read stage comprises a transistor 107 assembled as a follower source, having its gate connected to sense node SN. The drain of transistor 107 is connected to a node or rail of application of a high voltage, voltage V_{RT} in this example, and the source of transistor 107 is coupled, by a read transistor 109, to track OUT coming out of the pixel. In the shown example, transistors 103, 105, 107, and 109 of pixel 100 are N-channel MOS transistors. In operation, pixel 100 receives control signals TG, RST, and RS respectively applied to the gates of transistors 103, 105, and 109.

In a phase of initialization of photodiode 101 of pixel 100, transistor 105 may be turned on (signal RST in a high state in this example), which causes the initialization of the voltage of node SN to voltage V_{RT}, and then turned off (signal RST in a low state in this example), to isolate node SN from node V_{RT}. Transistor 103 can then be turned on (signal TG in a high state in this example), which causes the transfer of the charges stored in photodiode 101 onto read node SN. The voltage across photodiode 101 then becomes equal to the natural voltage of the diode, which results from the doping levels.

During a pixel integration phase (preceded by a photodiode initialization phase), transfer transistor 103 may be maintained off (signal TG in the low state in this example) to isolate acquisition node K from sense node SN. The electric charges generated in photodiode 101 under the effect of light then cause a progressive decrease of the voltage of acquisition node K.

During a pixel read phase (at the end of an integration phase), reset transistor 105 may be turned on (signal RST in the high state in this example), to initialize the voltage of node SN to the voltage of node V_{RT}, and then turned off (signal RST in the low state in this example) to isolate read node SN from node V_{RT}. Transistor 103 can then be turned on (signal TG in the high state in this example), which causes the transfer of the photogenerated charges stored at node K onto node SN, and marks the end of the integration phase. The potential of node K can then be transferred to output track OUT via transistors 107 and 109 (to achieve this, transistor 109 may be turned on—signal RS in a high state in this example), and then read by a read circuit, not shown, external to the pixel.

FIG. 2 is a simplified partial cross-section view of an example of a pixel 200 of a CMOS image sensor. In FIG. 2, only certain elements of pixel 200 have been shown, that is, a photodiode, a transfer transistor, a read region, and a reset transistor. Pixel 200 may however comprise other elements, for example, a read stage coupling the read region to an output track of the pixel.

The elements of pixel 200 shown in FIG. 2 are formed inside and on top of a region of a P-type doped semiconductor substrate 201, for example, a silicon substrate, delimited by insulating trenches 203, 205, for example, made of silicon oxide.

The photodiode is formed close to the surface of substrate 201, and comprises an N-type doped region 207 which extends, horizontally, approximately parallel to the surface of substrate 201 and, vertically, down to a relatively small depth, for example, approximately ranging from 0.1 to 0.5 μm. Region 207 is topped with a thin P-type doped region 209 which extends from the upper surface of the substrate to the upper surface of N-type region 207. N-type region 207 is thus totally delimited by P-type regions (substrate 201 and region 209 in the shown example). The photodiode of pixel 200 is a so-called pinned photodiode, having its cathode formed by region 207, and having its anode formed by P-type regions surrounding region 207. Region 207 defines a photogenerated charge storage area. In the absence of photogenerated charges, the voltage of storage region 207 depends on the doping levels of regions 207, 209, and 201 and on the photodiode dimensions.

The transfer transistor comprises an insulated gate electrode 211 formed on the upper surface of substrate 201, between region 207 and a floating N-type doped read region 213. The upper surface of read region 213, emerging at the surface of the substrate, may be coated with a contact metallization, not shown, from which the voltage of sense node SN can be read via a read circuit, not shown. In this example, in top view, electrode 211 has an edge which approximately coincides with an edge of region 207, and an opposite edge which approximately coincides with an edge of read region 213. Thus, in this example, electrode 211 extends between storage region 207 and read region 211 but overhangs neither region 207 nor region 213 (to within possible manufacturing inaccuracies).

Region 215 of substrate 201 located under gate 211, in the upper portion of substrate 201, will be called transfer region hereafter. In operation, storage region 207 forms a source region of the transfer transistor, read region 213 forms a drain region of the transfer transistor, and transfer region 215 forms a channel-forming region of the transfer transistor.

In the shown example, pixel 200 further comprises a reset transistor comprising an insulated gate electrode 217 formed on the upper surface of substrate 201, between read region 213 and a heavily-doped N-type region 219 of application of a reset voltage V_{RT}. Region 219 emerges at the surface of the substrate and may be coated with a metallization, not shown, on which voltage V_{RT} can be applied.

Pixel 200 of FIG. 2 operates as follows.

When the image sensor is illuminated, photons penetrate into the substrate and form electron/hole pairs therein. The electrons of the photogenerated pairs are attracted by N-type doped storage region 207 of the photodiode.

During a charge collection phase, a zero or slightly negative voltage (TG) may be applied to gate 211 of the transfer transistor, and the electrons are collected in storage region 207. P-type substrate 201 may be biased to a low reference voltage GND, for example, the ground.

Then, during a charge transfer phase, electrons collected in storage region 207 are transferred to read region 213. For this purpose, an adapted transfer voltage (TG) is applied to gate 211 of the transfer transistor. During a transfer, electrons leave region 207 from its side coinciding, in top view, with an edge of gate 211, and are transferred into read region 213, through a channel formed in region 215 under the effect of the voltage applied to gate 211.

A disadvantage is that, in use, relatively high quantities of remanent charges can be observed in photosensitive cells of image sensors such as that described in relation with FIG. 2. Such remanent charges cause a degradation of the image quality.

An image sensor photosensitive cell having decreased quantities of remanent charges is thus desirable.

The inventors have studied the origin of the remanent charges observed in an image sensor photosensitive cell of the type illustrated in FIG. 2.

The electron transfer path from storage region 207 to read region 213, when an adapted transfer voltage is applied to gate 211, is shown in dotted lines in FIG. 2. Electrons start from a point A in storage region 207 of the photodiode, and first head towards the upper surface of substrate region 215 located under gate 211. Electrons pass, at a point B, into the channel region of the transfer transistor. Once in this channel region close to the upper surface of the substrate, electrons are directed towards heavily-doped N-type read region 213, while remaining close to the substrate surface. At a point C, electrons reach read region 213.

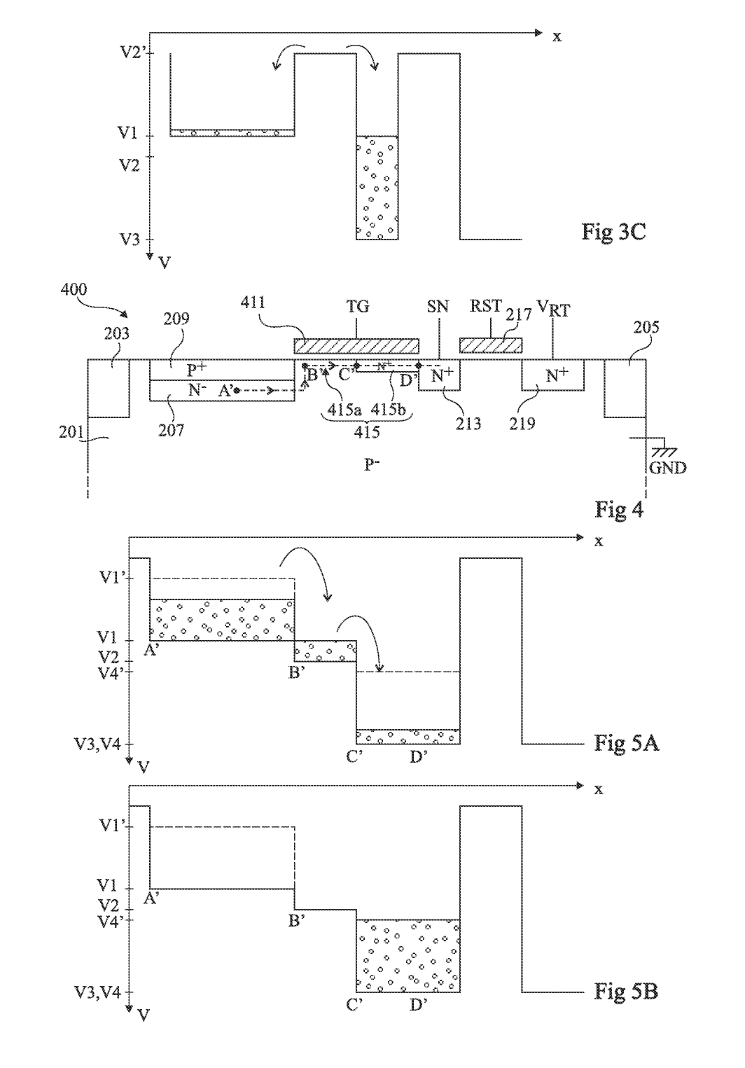

FIGS. 3A and 3B are profiles of voltage V according to position x along the electron transfer path in the photosensitive cell of FIG. 2, when the transfer transistor is in the conductive state. FIG. 3A schematically illustrates the pixel behavior at the beginning of a transfer phase, that is, just after the transfer transistor has been turned on at the end of an integration phase, and FIG. 3B schematically illustrates the pixel behavior at the end of a transfer phase, that is just before the transfer transistor is blocked again.

In the absence of illumination and after a charge transfer phase, the maximum voltage in storage region 207 is equal to V1. The value of voltage V1 depends on the photodiode dimensions and on the doping levels of the regions forming the photodiode.

When the photosensitive cell is illuminated, during a charge collection phase, the transfer transistor being in the off state, electrons are stored in storage region 207. The voltage of storage region 207 decreases to a value V1′. The voltage of read region 213 is equal to a value V3, greater than value V1, imposed during a reset or precharge phase.

During the charge transfer phase, when the transistor is in the conductive state, voltage V2 of transfer region 215, or channel region of the transistor, set by the voltage applied to gate 211, is greater than voltage V1. A potential drop thus appears at point B. Voltage V2 is lower than voltage V3, so that a potential drop also appears at point C, at least at the beginning of the transfer phase. The voltage of read region 213 decreases as electrons transit from storage region 207 to read region 213, down to a value V3′, while the voltage of storage region 207 increases up to value V1.

If the quantity of photogenerated electrons present in storage region 207 exceeds a given threshold, voltage V3′ of the read region at the end of the transfer may be lower than voltage V2. Photogenerated charge may thus store under gate 211, in region 215. This is shown in FIGS. 3A and 3B where voltage V3′ is between voltages V1 and V2.

FIG. 3C is a profile of voltage V according to position x along the electron transfer path in the photosensitive cell of FIG. 2, when the transfer transistor switches to the off state, at the end of the transfer phase shown in FIGS. 3A and 3B.

When a zero or slightly negative voltage (TG) is applied to gate 211 of the transfer transistor, the voltage of channel region 215 passes from value V2 to a value V2′ smaller than value V2 and than value V1. At this time, part of the photogenerated electrons stored under transfer gate 211 at the end of the transfer phase—those located close to storage region 207—returns to storage region 207, the other part—those located close to read region 213—being transferred into read region 213.

The inventors impute the relatively high quantities of remanent charges observed in photosensitive cells of the type illustrated in FIG. 2 to this phenomenon. During in image detection cycle, not all the electrons collected in storage region 207 of the pixel during the charge collection phase are transferred to read region 213 during the charge transfer phase, which disturbs the detection of this image and the detection of the next images.

To avoid for electrons to return to storage region 207 when the transfer transistor switches to the off state, the inventors provide forming an N-type doped region at the surface of the substrate under transfer gate 211, close to read region 211.

FIG. 4 is a simplified partial cross-section view of an embodiment of a pixel 400 of a CMOS image sensor. The elements common with FIG. 2 are designated with the same reference numerals and will not be described in detail again hereafter. Hereafter, only the differences between the structures of FIGS. 2 and 4 will be highlighted.

Pixel 400 of FIG. 4 differs from pixel 200 of FIG. 2 by the structure of the transfer transistor coupling N-type storage region 207 of the photodiode to N-type read region 213 of the pixel.

In pixel 400, the transfer transistor comprises an insulated gate electrode 411 formed on the upper surface of substrate 201, between storage region 207 and read region 213. In this example, in top view, electrode 411 has an edge which approximately coincides with an edge of region 207, and an opposite edge which approximately coincides with an edge of read region 213. Thus, in this example, electrode 411 extends between storage region 207 and read region 411 but overhangs neither region 207 nor region 213 (to within possible manufacturing inaccuracies). Alternative embodiments where electrode 411 partly overhangs the photodiode charge storage region may however be provided, for example, in the case of a vertical pinned photodiode, where the storage region extends vertically in the substrate down to a relatively large depth, for example, greater than 1 μm.

Region 415 located under the gate, in the upper portion of substrate 201, will be called transfer region hereafter. In operation, storage region 207 forms a source region of the transfer transistor, read region 213 forms a drain region of the transfer transistor, and transfer region 415 forms a channel-forming region of the transfer transistor.

According to an aspect of the embodiment of FIG. 4, transfer region 415 is divided into two areas 415a, 415b, each extending from the substrate surface and having a common lateral edge. Area 415a is located on the photodiode side. It extends laterally between the photodiode and area 415b. Area 415b is located on the side of read region 213. It extends laterally between area 415a and read region 213.

Area 415a is P-type doped. It preferably has the same doping level as substrate 201, and substantially behaves in the same way as transfer region 215 of the pixel of FIG. 2. As a variation, it may however be provided for P-type area 415a to have a doping level different from that of substrate 201.

Area 415b is N-type doped. In this example, the doping level of area 415b is identical to that of read region 213. As a variation, it may however be provided for N-type area 415b to have a doping level different from that of read region 213. Area 415b is located on the electron transfer path. The thickness and the doping level of area 415b, as well as the value of the nominal voltage applied to gate 411 during and outside charge transfer phases, are selected so that area 415b is fully depleted of photogenerated charges outside of transfer phases, and is capable of storing photogenerated charges (that is, is not fully depleted) during transfer phases.

As can be seen in FIG. 4, the gate electrode 411 completely tops the entire transfer region 415 in that the gate electrode extends completely from a position directly above the shared edge of the transfer region 415 and storage region 207 at least to a position directly above the shared edge of the transfer region 415 and the read region 213. In one embodiment, the gate electrode 411 extends beyond the shared edge of the transfer region 415 and storage region 207 to top a portion of the storage region 207.

As a non-limiting example, the doping levels of substrate 201, of storage region 207, of P-type region 209, and of read region 213 may range between respectively 5*10¹⁴ and 5*10¹⁵ atoms/cm³, 5*10¹⁶ and 5*10¹⁷ atoms/cm³, 10¹⁷ and 5*10¹⁸ atoms/cm³, and 10¹⁸ and 10¹⁹ atoms/cm³. Areas 415a and 415b may respectively have the same doping level as substrate 201 and the same doping level as read region 213, and area 415b may have a thickness ranging between 100 and 500 nanometers.

Reset voltage V_{RT} may approximately range between 2 and 3 V, and may for example be approximately 2 V. The natural voltage of storage region 207 after a transfer may approximately range between 1 and 2 V and may for example be approximately 1.3 V. The voltage applied to gate 411 during a transfer phase may approximately range between 2 and 4 V and may for example be approximately 3.3 V. The voltage applied to gate 411 to maintain the transistor in the off state (outside of transfer phases) may approximately range between 0 and −1 V and may for example be approximately −0.8 V.

The electron transfer path from storage region 207 to read region 213, when an adapted voltage (TG) is applied to gate 411, is shown in dotted lines in FIG. 4. Electrons for example leave from a point A′ in storage region 207 of the photodiode, and head towards the upper surface of the substrate located under gate 411. Electrons pass, at a point B′, into P-type area 415a, which, under the effect of the transfer voltage applied to gate 411, is inverted. Once in area 415a, electrons head towards N-type area 415b. At a point C′, the electrons reach area 415b, and can then either pass into read area 213 at a point D′, or stay in area 415b.

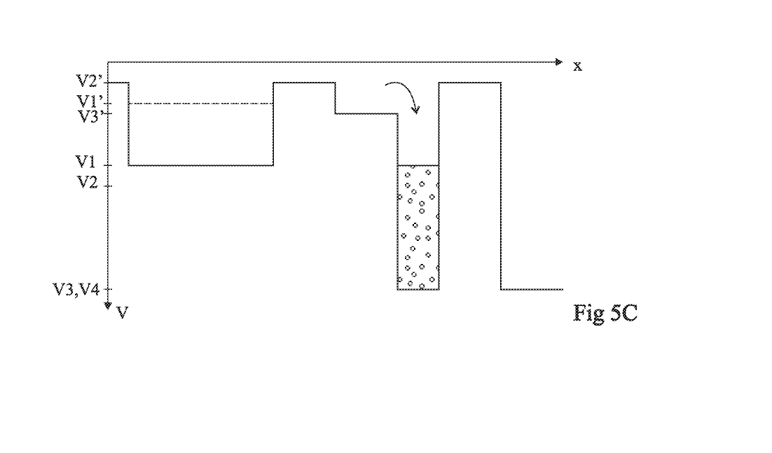

FIGS. 5A and 5B are profiles of voltage V versus position x along the electron transfer path in the photosensitive cell of FIG. 4, when the transfer transistor is in the conductive state. FIG. 5A schematically illustrates the behavior of pixel 400 at the beginning of a transfer phase, that is, just after the transfer transistor has been turned on at the end of an integration phase, and FIG. 5B schematically illustrates the behavior of pixel 400 at the end of a transfer phase, that is, just before the transfer transistor is blocked again.

In the absence of illumination and after a charge transfer phase, the maximum voltage in storage region 207 is equal to V1.

When the photosensitive cell is illuminated, during a charge collection phase, transfer transistor being in the off state, electrons are stored in storage region 207. The voltage of storage region 207 decreases all the way to a value V1′. The voltage of read region 213 is equal to a value V4, greater than value V1, imposed during a reset phase.

During the charge transfer phase, when the transistor is in the conductive state, voltage V2 of P type transfer area 415a, set by the voltage applied to gate 411, ranges between voltage V1 and voltage V4. A voltage drop thus appear at point B′.

During the charge transfer phase, voltage V3 of N-type transfer area 415b is greater than voltage V2. A voltage drop thus also appear at point C′. In this example, when the transistor is in the conductive state, voltage V3 of N-type transfer area 415b is substantially equal to voltage V4 of read region 213. This results from the fact that the N-type doping level is relatively high and substantially identical in regions 415b and 213. N-type area 415b thus behaves as an extension of drain region 213 of the transfer transistor.

The voltage of read region 213 decreases as electrons transit from storage region 207 to read region 213, down to a value V4′, while the voltage of storage region 207 increases up to value V1. The transferred electrons distribute in read region 213 and in area 415b.

A difference with the cell of FIG. 2 is that, while in certain illumination conditions, photogenerated electrons are capable of being stored under the entire surface of gate 211 at the end of a transfer phase in the cell of FIG. 2, in the cell of FIG. 4, in the same illumination conditions, the excess photogenerated electrons are only stored in area 415b located in the vicinity of read region 213, and are not stored in area 415a located in the vicinity of the photodiode.

FIG. 5C is a profile of voltage V according to position x along the electron transfer path in the photosensitive cell of FIG. 4, when the transfer transistor switches to the off state, just after the transfer phase shown in FIGS. 5A and 5B.

When a zero or slightly negative voltage (TG) is applied to gate 411 of the transfer transistor, the voltage of area 415a decreases from value V2 to a value V2′ smaller than value V2 and than value V1, and the voltage of area 415b passes from value V3 to a value V3′ smaller than value V2 and than value V1 but greater than value V2′. There thus is a voltage drop between area 415a and area 415b.

Due to this voltage drop and to the fact that area 415a stores no excess photogenerated electrons at the end of the transfer, all the excess photogenerated electrons stored under the gate at the end of the transfer are discharged into read region 213 when the transfer transistor switches to the off state.

N-type area 415b of transfer region 415 thus enables to avoid for photogenerated charges to return to the photodiode accumulation area at the end of a transfer phase.

In other words, in the cell of FIG. 4, the transfer transistor coupling storage region 207 and read region 213 comprises, under its gate, two distinct areas defining distinct threshold voltages of the transistor, behaving as a check valve for the transferred charges.

This enables to avoid or to strongly limit the presence of remanent charges in the photosensitive cells of an image sensor.

Specific embodiments have been described. Various alterations, modifications, and improvements will readily occur to those skilled in the art.

In particular, although a photosensitive cell of an image sensor comprising a storage region and a read region which are N-type doped, formed in a P-type doped substrate, has been described, the photosensitive cell may comprise P-type doped storage and read regions formed in an N-type doped substrate or well. In this case, the conductivity types of all the described regions may be inverted. The charges collected in storage region 207 and then transferred to read node 213 will then no longer be electrons, but holes. It will be within the abilities of those skilled in the art to accordingly adapt the doping levels and the control voltages to be applied to the cell.

Further, the described embodiments are not limited to the above-mentioned numerical examples of doping levels, or dimensions, and of control voltages.

Such alterations, modifications, and improvements are intended to be part of this disclosure, and are intended to be within the spirit and the scope of the present invention. Accordingly, the foregoing description is by way of example only and is not intended to be limiting.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. An image sensor cell, comprising:
a storage region formed in a semiconductor substrate of a first conductivity type, the storage region being of a second conductivity type;
a read region of the second conductivity type formed in the substrate;
a transfer region located between the storage region and the read region; and
a transfer gate completely topping the transfer region and which does not or does not totally top the storage region,
wherein the transfer region comprises a first area of the first conductivity type adjacent to the storage region, and a second area of the second conductivity type extending between the first area and the read region.

2. The cell of claim 1, wherein the first and second areas both extend all the way to a surface of the substrate and have a common lateral edge.

3. The cell of claim 1, wherein the second area has a thickness and doping level selected so that:
the second area is configured to store photogenerated charges in a first operating mode in response to a voltage ranging between 2 and 4 V being applied to the gate; and
the second area is configured to be fully depleted of photogenerated charges in a second operating mode in response to a voltage ranging between −1 and 0 V being applied to the gate.

4. The cell of claim 1, wherein the second area and the read region having substantially equal doping levels.

5. The cell of claim 1, wherein the first area and the substrate have substantially equal doping levels.

6. The cell of claim 1, wherein the storage region is a floating region of a pinned photodiode.

7. The cell of claim 1, wherein the storage region is entirely delimited by regions of the first conductivity type.

8. The cell of claim 1, further comprising a region of the first conductivity type topping the storage region, the region of the first conductivity type having a higher doping level than the substrate.

9. The cell of claim 1, wherein the first and second conductivity types respectively are type P and type N.

10. An image sensor comprising a plurality of image sensor cells each including:
a storage region formed in a semiconductor substrate of a first conductivity type, the storage region being of a second conductivity type;
a read region of the second conductivity type formed in the substrate;
a transfer region located between the storage region and the read region; and
a transfer gate completely topping the transfer region and which does not or does not totally top the storage region,
wherein the transfer region comprises a first area of the first conductivity type adjacent to the storage region, and a second area of the second conductivity type extending between the first area and the read region.

11. The image sensor of claim 10, wherein the first and second areas both extend all the way to a surface of the substrate and have a common lateral edge.

12. The image sensor of claim 10, wherein the second area has a thickness and doping level selected so that:
the second area is configured to store photogenerated charges in a first operating mode in response to a voltage ranging between 2 and 4 V being applied to the gate; and
the second area is configured to be fully depleted of photogenerated charges in a second operating mode in response to a voltage ranging between −1 and 0 V being applied to the gate.

13. The image sensor of claim 10, wherein the second area and the read region having substantially equal doping levels.

14. The image sensor of claim 10, wherein the first area and the substrate have substantially equal doping levels.

15. The image sensor of claim 10, wherein the storage region is a floating region of a pinned photodiode.

16. The image sensor of claim 10, wherein the storage region is entirely delimited by regions of the first conductivity type.

17. The image sensor of claim 10, wherein each cell includes a region of the first conductivity type topping the storage region of the cell, the region of the first conductivity type having a higher doping level than the substrate.

18. The image sensor of claim 10, wherein the first and second conductivity types respectively are type P and type N.
